(19) United States
(12) Patent Application Publication
(10) Pub. No.: US 2009/0181315 A1
(43) Pub. Date: Jul. 16, 2009

(54) PRODUCTION OF MICRO- AND NANOPORE MASS ARRANGEMENTS BY SELF-ORGANIZATION OF NANOPARTICLES AND SUBLIMATION TECHNOLOGY

(75) Inventors: Joachim Spatz, Heidenheim (DE); Theobald Lohmueller, Nuernberg (DE)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignee: Max-Planck-Gesellschaft zur Foerderung der Wissenschaflen e.V., Muenchen (DE)

(21) Appl. No.: 12/302,733

(22) PCT Filed: May 29, 2007
(86) PCT No.: PCT/EP07/04749

§ 371 Date: Dec. 16, 2008

(30) Foreign Application Priority Data
May 30, 2006 (DE) 10 2006 025 121.0

(51) Int. Cl. G03F 1/00

(52) U.S. Cl. 430/5

(57) ABSTRACT

The invention relates to a method for the production of micro- and/or nanopore mass arrangements on a substrate including functionalization of the substrate surface in selected areas; deposition of colloidal particles that have the capacity to selectively bond to the functionalized areas of the substrate surface from an aqueous dispersion on the substrate surface, during which an ordered monolayer of the particles forms on the substrate surface; separation of non-bound colloidal particles; freezing of the substrate; and sublimation of the residual water on the substrate in the vacuum, during which the short-range order of the particle monolayer is preserved.

The present invention relates to a novel method for the production of large-area micro- and nanopore mass arrangements by pure self-organization. The pore arrangement can be controlled on the substrate surface in discrete areas. The size of the pores and the lateral pore distance can be adjusted on the micro- and nanometer scale.

Micro- and nanopores respectively pore arrangements have numerous applications, for example, as biomimetic model systems for the simulation and elucidation of processes taking place on the cellular membrane level. The intra- and intercellular ion- and molecule transport and the maintaining of the electric potential between cells and their environment are regulated by nanopore systems. Thus, for example, the cell nucleus of eukaryotic life forms is separated by a nuclear membrane permeated with pores from the rest of the cell. The reciprocal transport of RNA, proteins and molecules between nucleus and cytoplasm through these membrane openings is of decisive significance for cell-regulating processes such as growth and cell division. [M. Beck, F. Förster, M. Ecke, J. M. Plitzko, F. Melchior, G. Gerisch, W. Baumeister, O. Medalia, Science, vol. 306, Issue 5700, 1387-1390, Nov. 19, 2004]. Furthermore, applications as electronic structural elements, in the biosensor engineering as well as in the analytic-diagnostic area, as active substance depots and for the delivery of active substances are being investigated [T. A. Desai et al., “Nanopore Technology for Biomedical Applications”].

Such structures can be used in combination with technically established optical lithographic methods as a mask for the preparation of further nanoscale materials [S. A. Knaack, J. Eddington, Q. Leonard, F. Cerrina and M. Onellion, “Dense arrays of nanopores as x-ray lithography masks”, Appl. Phys. Let., vol. 84, No. 17, Apr. 26, 2004]. Moreover, structure and depth of the nanopores can be further modified by plasma- or wet-chemical etching methods. Such pore fields can serve as a form for the production and spatial arrangement of nanowires, nanorods or nanotubes [R. B. Wehrspohn, “Geordnete poröse Nanostrukturen—ein Baukastensystem für die Photonik [Translation from German: Ordered Porous Nanostructures, a Building Block System for the Photonic Technology]”, postdoctorial thesis, University of Halle-Wittenberg, 2003].

Nanoporous filter systems are a very promising method for the minimizing of the emission of nanometer particles, the so-called fine dust that is produced in motor vehicle engines and that is substantially made responsible for the negative health effects of air contamination. The filter effect is based here on the mechanical blocking of particles above a certain size and/or the catalytic conversion of them or of toxic pollutants on the insides of the pores [H. Presting, U. König, “Future nanotechnology developments for automotive applications”, Mat. Science and Eng. C., 23, 737-741, 2003].

The technical production strategies for such large-area micro- and nanopore mass arrangements were previously limited to optical lithographic methods and imprint lithographic methods. These known methods are associated with a high technical expense and consequently very cost-intensive and time-intensive.

The object of the present invention therefore is to provide a new improved method with which such structures can be produced more simply and more economically, especially for all above-named applications, as well as to provide the structures produced therewith.

These objects are achieved in accordance with the invention by the method according to Claim 1 and the lithographic mask according to Claim 14. Preferred embodiments of the invention are subject matter of the dependent Claims 2-13.

The method in accordance with the invention is based on the use of self-organizing colloidal nano- and microparticles for the production of large-area (>cm²) pore fields on a plurality of substrates, e.g., metals, metal oxides, crystals such as, e.g., CaF₂, glass, silicon and plastic surfaces, e.g., thermoplastic, elastic, structure-cross-linked or cross-linked polymers in controlled patterns. The concept “colloids”, as used here, signifies particles of a typical length scale of 10-10⁴ nm across all substance classes. The self-organization of these particles is used by nature and technology to produce structured materials that have interesting optical, mechanical or chemical qualities [see Eiden, “Kolloide: Alte Materialien, neue Anwendungen”, Nachrichten aus der Chemie, 52, 1035-1038, October 2004].

The method in accordance with the invention for the production of micro- and/or nanopore mass arrangements on a substrate comprises

a) functionalization of the substrate surface in selected areas;
b) deposition of colloidal particles that have the capacity to selectively bond to the functionalized areas of the substrate surface from an aqueous dispersion on the substrate surface, during which an ordered monolayer of the particles forms on the substrate surface;
c) separation of non-bound colloidal particles;
d) freezing of the substrate; and
e) sublimation of the residual water on the substrate in the vacuum, during which the short-range order of the particle monolayer is preserved.

In a more specific embodiment the method furthermore comprises

f) application of a metallic coating on the dried substrate surface;
g) subsequent removal of the particles from the substrate surface, while a porous metallic layer remains.

In an even more specific embodiment the method furthermore comprises

h) fine adjustment of pore size and pore distance by a posttreatment of the substrate surface, e.g., by plasma etching, currentless metallization or galvanization.

The functionalization of the substrate surface typically takes place by application of an adhesion promoter. Substrates can be a plurality of materials, e.g., glass/quartz glass, silicon, silicon nitrite, metals, metal oxides, crystals such as, e.g., CaF₂, and plastics. Basically all adhesion promoters known in the state of the art can be considered as adhesion promoters. In one embodiment of the invention the adhesion promoter is bound physically, e.g., by adsorption, to the substrate surface. A few non-limiting examples thereof are organic polymers, e.g., polyethylene imine (PEI) and compounds with ionic or ionizable functional groups, e.g., polyamide resins. Also polymers such as PEG, polypropylene glycol, polyvinyl pyrrolidone or polyvinyl alcohols can be used, preferably in combination with a plasma treatment (Y.-S. Lin, H. K. Yasuda, Journal of Applied Polymer Science, vol. 67, 855-863 (1998)). Another suitable substance class is proteins, e.g., bovine serum albumin (BSA).

In an alternative embodiment the adhesion promoter is chemically bound to the substrate surface. Specific examples for such adhesion promoters are functional organosilanes or silane derivatives, e.g., of the general formula (X)₃SiR′Y, in which X=halogen, OR, NR₂; Y=amine, methacrylate, epoxide, thiol, carboxyl. A further method for bonding specific, especially ionic functional groups on organic substrate surfaces is the coating with photo initiators that are activated by UV light. Examples for such initiators are functionalized acrylate- and methacrylate compounds (M. Kunz, M. Bauer, Vakuum in Forschung u. Praxis (2001), No. 2, 115-120; WO 00/24527).

Inorganic adhesion promoters, e.g., phosphate-, chromate- and titanate layers can also be used.

Even several adhesion promoters, bound physically as well as chemically, can be used.

The colloidal particles used in the method of the present invention typically have a positive or negative surface charge and the functionalization of the substrate surface produces a surface charge opposite thereof in the selected areas and brings about the bonding of the particles by electrostatic interaction.

Basically all colloidal particles that can bond to the functionalized substrate surface are suitable as colloidal particles for use in the present invention. This bonding preferably takes place by electrostatic interaction. More particularly, the colloidal particles are selected from non-substituted or substituted organic polymers, e.g., polystyrene (PS), poly(methyl)methacrylate (PMMA), polyvinyltoluene (PVT), styrene/butadiene-copolymer (SB), styrene/vinyltoluene copolymer (S/VT), styrene/divinylbenzene (S/DVB), or inorganic particles, e.g., silicon dioxide, titanium dioxide, zirconium dioxide. The organic polymers are preferably substituted with amino-, carboxy- or sulfate groups. Such colloids are commercially obtainable with high monodispersity.

The colloidal particles used in accordance with the invention typically have a mean size in a range of 10 nm-10 μm, preferably 50 nm-5 μm, more preferably 100 nm-2 μm.

The particle layer is produced by immersion of the substrate in a dispersion of colloids in an aqueous solvent, e.g., water or a mixture of water and an organic solvent miscible with water, e.g., an alcohol such as methanol, ethanol, propanol. A person skilled in the art can readily determine a suitable solvent in dependency of the reaction partners used and of the required process conditions. Usually the preferred solvent is water. Size and structure can be purposefully regulated and controlled by the functionalization of discrete areas with a suitable adhesion promoter.

After the coating the substrate is usually washed with water in order to remove excess, non-adhering colloids and subsequently frozen in the moist state with, e.g., liquid nitrogen. In the case of a high particle density or increasing particle size, capillary forces occurring during the normal drying of the monolayer result in an undesired aggregate formation into small particle clusters and in a destruction of the short-range order. This means that the particle layer produced as above can not be used as mask for the deposition of a cover layer for producing nanopore fields without a further treatment. Traditionally, for example, relatively expensive selective plasma processes were used for such a further treatment of monolayers. In contrast thereto, in the method of the present invention a sublimation technique is used for the drying in order to avoid the occurrence of capillary interactions. The residual water between the colloids is removed by freeze-drying in the vacuum and a congregation of the particles is prevented in this manner. The structure formed by self-organization and mutual rejection of the particles remains preserved. Therefore, a decisive advantage of the sublimation method consists in that the particle layer can be directly used to produce nanopore fields.

In an embodiment of the method in accordance with the invention the nano- and micropore mass arrangement produced is used as lithographic mask for the application of a metal layer on a functional carrier material (FIG. 1). A plurality of materials such as, for example, glass/quartz glass, silicon, silicon nitrite, plastics or the other substrates already indicated above can be considered as substrate.

The particle layer is produced by immersing the substrate in a dispersion of colloids in an aqueous solvent, for example, water or a mixture of water and an organic solvent, preferably water. The size and structure can be purposefully regulated and controlled here by functionalization of discrete areas with a suitable adhesion promoter. The adhesion of the charged spherules to the surface preferably takes place based on electrostatic interactions.

After the decoration the substrate is first washed with water and subsequently the moist sample is frozen with, e.g., liquid nitrogen. In the case of a high particle density or increasing particle size, capillary forces occurring during the drying of the monolayer result in an undesired aggregate formation into small particle clusters. In order to avoid this, the residual water between the colloids is sublimated off in the vacuum so that the structure of the short-range order between the particles resulting from the mutual electrostatic rejection remains preserved (FIG. 2).

After the vapor-depositing of the surface with a metal the particles are subsequently removed wet-chemically or in the ultrasonic bath. A porous coating remains on the substrate that can be used in turn as etching mask for the further processing. The quality of the pores as regards size and lateral distance as well as the degree of covering can be adjusted by appropriately selected process parameters such as the saline concentration and the pH of the colloidal dispersion as well as the strength of the surface charge of the particles and of the substrate. The pore diameter and the pore distances can be additionally controlled in this method by isotropic plasma etching of the particle mask before the metal coating or by currentless metallization or galvanization of the pore mask from a metallic saline solution after the particle lift-off. The etching method is suitable in particular for surfaces that resist the material stress by a plasma process whereas the second method offers itself for more sensitive materials.

### BRIEF DESCRIPTION OF THE FIGURES

FIG. 1 is a schematic representation of the method described in example 1 for the production of a pore mass arrangement on a substrate.

FIG. 2 shows the results of two methods for the drying of deposited particle layers in the comparison

a) traditional drying
b) sublimation.

FIG. 3 shows the dependency of the pore size on the particle diameter.

FIG. 4 shows the change of the particle diameter by an etching treatment of the particles.

The following examples serve to outline the present invention in more detail but without limiting it.

### EXAMPLE 1

### Production of a Pore Mass Arrangement on a Glass Substrate

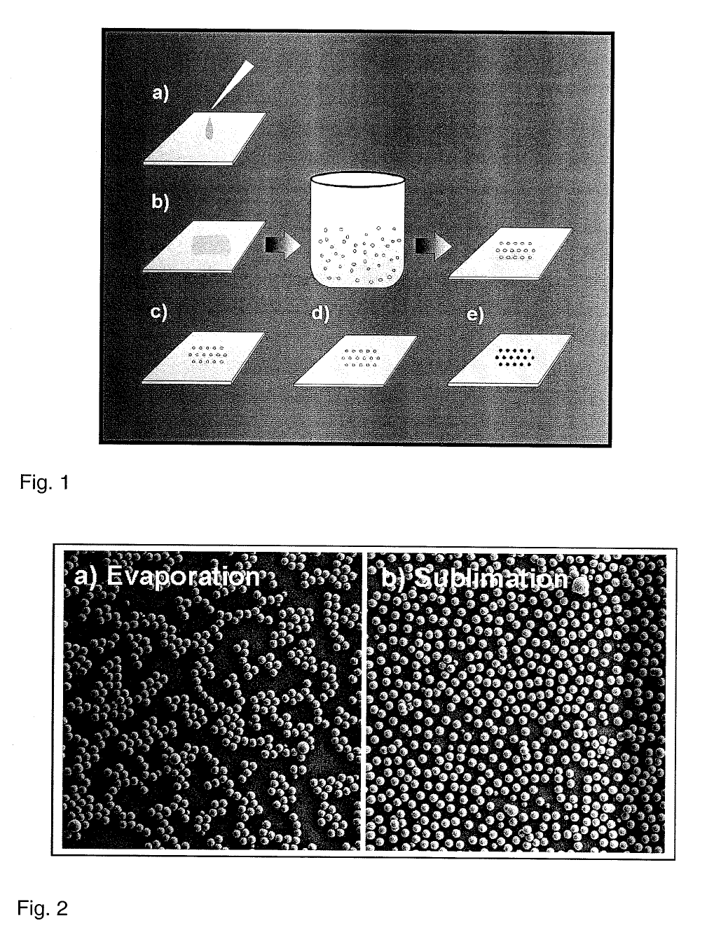

A 10 wt % solution of bovine serum albumin (BSA) and water is supplied on a cleaned small cover glass. After ten minutes exposure time an approximately 6 nm thick layer of BSA is adsorbed on the surface. The substrate is washed in a beaker glass with Milli-Q water and blown dry with nitrogen (FIG. 1a).

The functionalized glass platelet is immersed in a 2.5 wt % dispersion of polystyrene particles in water (FIG. 1b). On account of electrostatic interactions between the BSA film and the sulfate groups on the particle surface the adsorption takes place only on the areas of the substrate prepared with the adhesion promoter. The decorated surface is washed with water in order to remove excess non-adhering particles and the still wet sample immersed in liquid nitrogen. The particle short-range order produced in the liquid on account of the mutual electrostatic rejection remains preserved by the sudden icing.

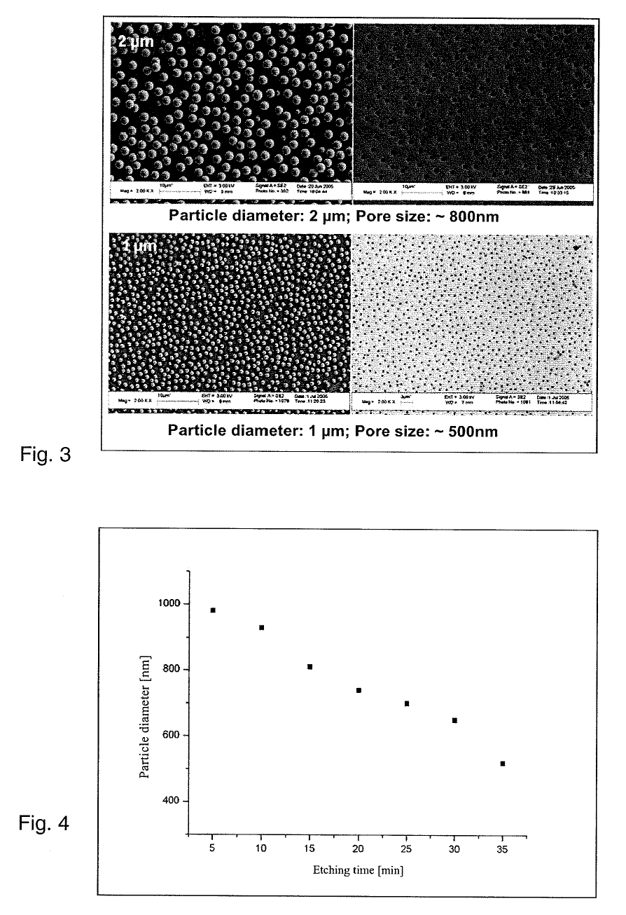

The frozen residue of dispersant is sublimated off in a Schlenck apparatus at a pressure of 10⁻¹-10⁻² mbar at room temperature. A metallic layer of the desired thickness is vapor-deposited on the dried particles in a sputtering process. Subsequently, the spherules are completely separated from the carrier surface in the ultrasonic bath. As a result, a porous metallic surface is obtained on the initial substrate with a pore diameter depending on the size and with a pore distance depending on the surface charge of the particles used (FIG. 3).

The pore diameter and pore distance can be additionally varied by a selective isotropic small etching of the spherules in a chemical plasma process before the application of the metallic layer (FIG. 4). It is also alternatively possible to alter the metallic pore mask by currentless or electrochemical deposition from an appropriate metallic saline solution and to control the pore parameters therewith.

### EXAMPLE 2

### Substrate Functionalization with Organosilanes

The functionalization of the substrate surface takes place by covalent bonding of 3-Aminopropyltriethoxysilane [NH₂(CH₂)Si(OC₂H₅)₃].

Glass substrates are cleaned at first 30 minutes in Caro's acid (H₂O₂/H₂SO₄ in a ratio of 1:3) and subsequently washed with Milli-Q water and methanol in the ultrasonic bath. The silanization of the surface takes place by immersion of the substrate in a solution of 290 ml methanol, 3 ml aminosilane, 5 ml H₂O and 18 μl glacial acetic acid with a reaction time of 12 hours. The glass platelet is finally washed several times with methanol and blown dry. [D. Cuvelier, O. Rossier, P. Bassereau, P. Nassoy, Eur. Biophys. J., 2003, 32, 342-354].

The bonding of monolayers of different organosilane derivatives could already be demonstrated on substrates such as, for example, silicon, aluminum oxide, quartz, glass, mica, zinc selenide, germanium oxide and gold. [A. Ulman, Chem. Rev., 1996, 96, 1533-1554].

The functionalized substrate is immersed in an aqueous dispersion of colloidal polystyrene particles. The further treatment takes place analogously to the procedure described in example 1.

### EXAMPLE 3

### Functionalization of Silicon Oxide Particles with Organosilanes

Inorganic silicon oxide particles are functionalized with triethoxysilyl-propyl-succinylanhydride (TESPSA). The silanization succeeds by incubation of the particles in a 10% solution of TESPSA in toluene for 16 hours [G. K. Toworfe, R. J. Composto, I. M. Shapiro, P. Ducheyne, Biomaterials, 2006, 27(4), 631-642]. The particles are separated from the reaction solution by centrifuging and ultrasonic treatment in several cleaning steps and washed with toluene and water. Finally, the carboxylated particles are re-suspended in Milli-Q water.

A 0.1% solution of polyethylene imine (PEI) in water is applied on a cleaned glass surface. After ten minutes exposure time a thin film of PEI is adsorbed on the surface. The substrate is washed in a beaker with Milli-Q water and dried. The particle decoration is effected due to attractive interactions between the amino groups on the substrate surface and the carboxyl groups of the SiO₂ particles.

The further treatment takes place analogously to the procedure described in example 1.

1. A process for the production of micro- and/or nanopore mass arrangements on a substrate, comprising
a) functionalization of a surface of the substrate in selected areas to provide functionalized areas of the substrate surface;
b) deposition of colloidal particles that have a capacity to selectively bond to the functionalized areas of the substrate surface from an aqueous dispersion on the substrate surface, during which an ordered monolayer of the particles forms on the substrate surface;
c) separation of non-bound colloidal particles;
d) freezing of the substrate; and
e) sublimation of residual water on the substrate in a vacuum, during which a close arrangement of the monolayer of particles is preserved.

2. The process according to claim 1, further comprising
f) application of a metallic coating on the substrate surface, wherein the substrate surface is dry;
g) subsequent removal of the particles from the substrate surface, while a porous metallic layer remains.

3. The process according to claim 2, further comprising
h) fine adjustment of pore size and pore distance by a post-treatment of the substrate surface by plasma etching, currentless metallization or galvanization.

4. The process according to claim 1, wherein the functionalization of the substrate surface takes place by an application of an adhesion promoter.

5. The process according to claim 4, wherein the adhesion promoter is bound physically to the substrate surface.

6. The process according to claim 4, wherein an organic polymer or a protein is bound to the substrate surface as the adhesion promoter.

7. The process according to claim 4, wherein the adhesion promoter is chemically bound to the substrate surface.

8. The process according to claim 7, wherein least one functional organosilane or silane derivative of the general formula (X)₃SiR′Y, in which X=halogen, OR, NR₂; Y=amine, methacrylate, epoxide, thiol, carboxyl, is bound to the substrate surface as the adhesion promoter.

9. The process according to claim 1, wherein the colloidal particles have a positive or negative surface charge and the functionalization of the substrate surface produces a surface charge opposite to the surface charge of the colloidal particles in the selected areas and the bonding of the particles takes place by electrostatic interaction.

10. The process according to claim 1, wherein the colloidal particles have a mean size in a range of 10 nm-10 μm.

11. The process according to claim 1, wherein the colloidal particles are selected from the group consisting of non-substituted or substituted organic polymers, e.g., polystyrene (PS), poly(methyl)methacrylate (PMMA), polyvinyltoluene (PVT), styrene/butadiene-copolymer (SB), styrene/vinyltoluene copolymer (S/VT), styrene/divinylbenzene (S/DVB), and inorganic particles.

12. The process according to claim 11, wherein the organic polymers are substituted with amino-, carboxy- or sulfate groups.

13. The process according to claim 2, wherein the removal of the particles in step g) takes place by a wet-chemical treatment or in an ultrasonic bath.

14. A lithographic mask, comprising a micro- and/or nanopore mask arrangement on a substrate that was produced with the process in accordance with claim 1.

15. The process according to claim 5, wherein the adhesion promoter is bound by adsorption to the substrate surface.

16. The process according to claim 6, wherein the adhesion promoter is ethylene imine (PEI), a polyamide resin, or bovine serum albumin (BSA).

17. The process according to claim 1, wherein the mean size of the colloidal particles is in a range of 100 m-2 μm.

18. The process according to claim 11, wherein the inorganic particles are silicon dioxide, titanium dioxide or zirconium dioxide.
